(19) United States
(12) Patent Application Publication
(10) Pub. No.: US 2011/0048679 A1
(43) Pub. Date: Mar. 3, 2011

(54) HEAT DISSIPATION DEVICE

(75) Inventors: YI-SHIH HSIEH, Tu-Cheng (TW); JIN-JUN RAO, KunShan City (CN)

(73) Assignees: FURUI PRECISE COMPONENT (KUNSHAN) CO., LTD., KunShan City (CN); FOXCONN TECHNOLOGY CO., LTD., Tu-Cheng (TW)

(21) Appl. No.: 12/581,176

(22) Filed: Oct. 19, 2009

(30) Foreign Application Priority Data
Aug. 26, 2009 (CN) 200910306122.2

(51) Int. Cl. F28D 15/04; F28F 7/00; H01L 23/427

(52) U.S. Cl. 165/104.26; 165/185

(57) ABSTRACT

A heat dissipation apparatus includes a flat heat pipe and a plurality of fins stacked together. Each fin defines a substantially rectangular-shaped receiving hole therein for receiving a condenser section of the flat heat pipe and a small-sized accommodating hole therein for accommodating a solder paste. A combining sidewall extends from an edge of the receiving hole, and includes elongated top and bottom planar plates, and a short plate extending from one end of the bottom planar plate towards the top planar plate. The accommodating hole is located at a junction of the top planar plate and the short plate. The solder paste accommodated in the accommodating hole is melted to flow into the receiving hole to fill up a clearance between the flat heat pipe and the combining sidewall to combine the flat heat pipe and the fins together.

### BACKGROUND

1. Technical Field

The present disclosure relates to heat dissipation apparatuses, and particularly to a heat dissipation apparatus for dissipating heat generated by electronic components.

2. Description of Related Art

It is widely acknowledged that heat is produced during operation of electronic components such as central processing units (CPUs) of computers. The heat produced by an electronic component must be quickly removed to protect the electronic component. Typically, a heat dissipation apparatus is provided to remove heat from the electronic component. The heat dissipation apparatus includes a heat pipe and a plurality of fins stacked together. One end of the heat pipe thermally connects with the electronic component, while the other end of the heat pipe connects with the fins. Heat generated by the electronic component is transferred to the fins via the heat pipe. Generally, the heat pipe and the fins are jointed together by soldering. Thus, the soldering quality directly and significantly affects a heat transfer efficiency between the heat pipe and the fins.

FIGS. 1 and 2 show a conventional heat dissipation apparatus 100. The conventional heat dissipation apparatus 100 includes a flat heat pipe 11 and a plurality of fins 12. Each fin 12 defines an elongated receiving hole 121 therein for receiving the flat heat pipe 11 and an accommodating hole 122 therein communicating with the receiving hole 121 for accommodating a solder paste 13. The accommodating hole 122 is located above the receiving hole 121 and at a center of a top edge of the receiving hole 121. A collar 123 extends vertically from a periphery of the receiving hole 121 and a periphery of the accommodating hole 122 of the fin 12.

Referring to FIG. 1, the flat heat pipe 11 is inserted in the receiving holes 121 of the fins 12. A clearance exists between the flat heat pipe 11 and the collar 123 of each fin 12 before the flat heat pipe 11 and the fins 12 being soldered together. The solder paste 13 is accommodated in the accommodating hole 122 of each fin 12. When soldering, the solder paste 13 is heated to its melting point. The molten solder paste 13 flows from the accommodating hole 122 into the receiving hole 121 of each fin 12 to fill up the clearance between the flat heat pipe 11 and the collar 123 of each fin 12. Referring to FIG. 2, after the molten solder paste 13 is cooled, a solder layer 14 is formed between the flat heat pipe 11 and the collar 123 of each fin 12, combining the flat heat pipe 11 and the fins 12 together.

However, in the above-mentioned heat dissipation apparatus 100, due to the accommodating hole 122 being located at a center of the top edge of the receiving hole 121, a flow distance of the molten solder from the accommodating hole 122 to a center point of a bottom edge of the receiving hole 121 is so longer that the molten solder paste can not fully fill up a clearance between a bottom planar face of the flat heat pipe 11 and a bottom planar plate of the collar 123. Thus, insufficient solder easily occurs between the bottom planar face of the flat heat pipe 11 and the bottom planar plate of the collar 123, which reduces the heat transfer efficiency between the flat heat pipe 11 and the fins 12. In addition, an effective contacting surface of the flat heat pipe 11 for combining with the collars 123 of the fin 12 includes both of the top and bottom planar faces of the flat heat pipe 11. The accommodating hole 122 at a center of the top edge of the receiving hole 121 reduces the effective contacting area of the flat heat pipe 11 for combining with the collars 123 of the fins 12.

For the foregoing reasons, therefore, there is a need in the art for a heat dissipation apparatus which overcomes the limitations described.

### BRIEF DESCRIPTION OF THE DRAWINGS

Many aspects of the present embodiment can be better understood with reference to the following drawings. The components in the drawings are not necessarily drawn to scale, the emphasis instead being placed upon clearly illustrating the principles of the present embodiment. Moreover, in the drawings, like reference numerals designate corresponding parts throughout the several views.

FIG. 1 is a cross-sectional view of a conventional heat dissipation apparatus, showing a state before a flat heat pipe and fins thereof are soldered together.

FIG. 2 is similar to FIG. 1, but showing a situation after the flat heat pipe and the fins of the heat dissipation apparatus have been soldered together.

FIG. 3 is an isometric view of a heat dissipation apparatus in accordance with a first embodiment, with a fin thereof being separated therefrom for a better illustration.

FIG. 4 is a cross-sectional view of the heat dissipation apparatus of FIG. 3, showing a state before a flat heat pipe and fins thereof are soldered together.

FIG. 5 is similar to FIG. 4, but showing a state after the flat heat pipe and the fins of the heat dissipation apparatus have been soldered together.

FIG. 6 is a cross-sectional view of a heat dissipation apparatus in accordance with a second embodiment.

FIG. 7 is a cross-sectional view of a heat dissipation apparatus in accordance with a third embodiment, showing a state before a flat heat pipe and fins thereof are soldered together.

FIG. 8 is similar to FIG. 7, but showing a state after the flat heat pipe and the fins of the heat dissipation apparatus have been soldered together.

FIG. 9 is a cross-sectional view of a heat dissipation apparatus in accordance with a fourth embodiment.

FIG. 10 is a cross-sectional view of a heat dissipation apparatus in accordance with a fifth embodiment.

### DETAILED DESCRIPTION

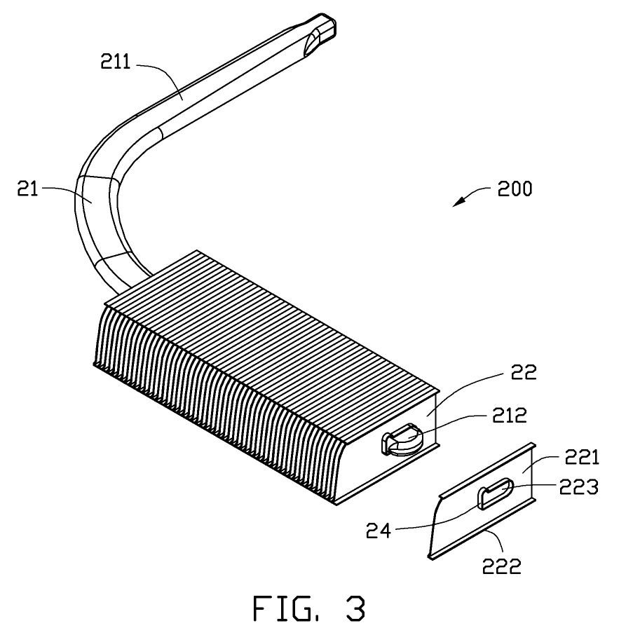

Referring to FIG. 3, a heat dissipation apparatus 200 according to a first embodiment includes a flat heat pipe 21 and a plurality of fins 22 stacked together. The flat heat pipe 21 has an L-shaped configuration. The flat heat pipe 21 includes an evaporator section 211 used for thermally connecting with an electronic component (not shown), and a condenser section 212 thermally connecting with the fins 22 to transfer heat therebetween.

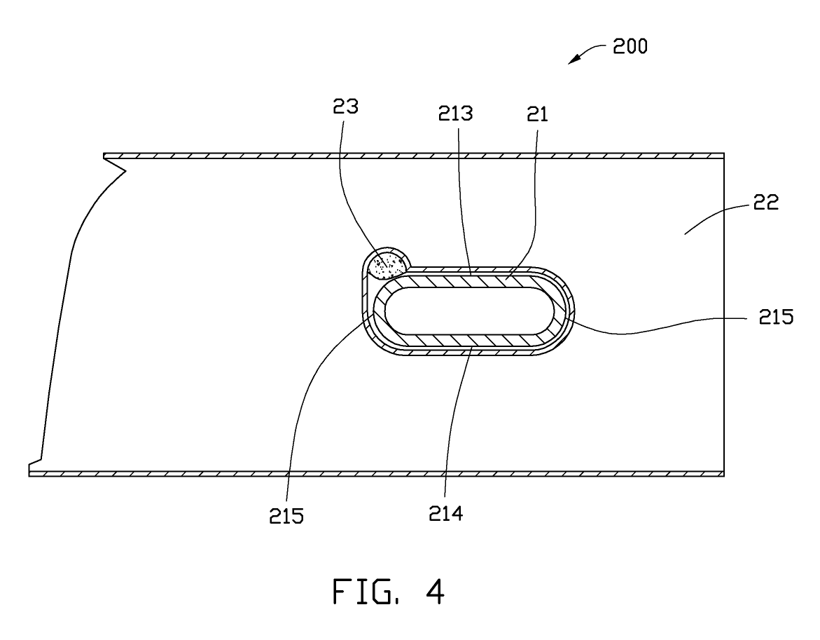

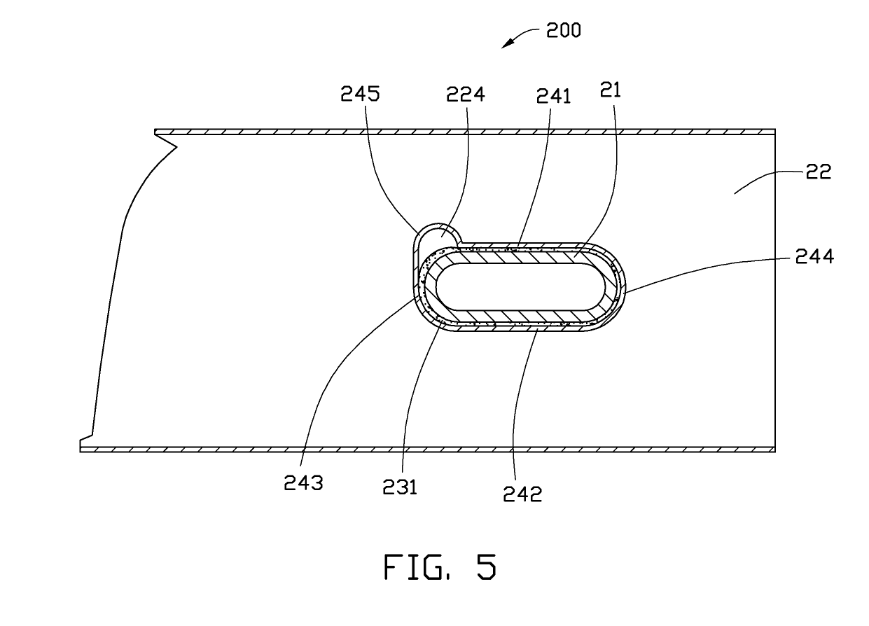

Referring also to FIGS. 4 and 5, an outer surface of the flat heat pipe 21 includes a top planar face 213, a bottom planar face 214 opposite and parallel to the top planar face 213, and two curved faces 215 respectively located at two opposite sides of the flat heat pipe 21 and connected between the top planar face 213 and the bottom planar face 214.

Each fin 22 includes a main body 221 and two flanges 222 bending from top and bottom ends of the main body 221. The fin 22 defines an elongated receiving hole 223 therein for receiving the condenser section 212 of the flat heat pipe 21. The receiving hole 223 is substantially rectangular-shaped, with straight, parallel top and bottom sides, an arced right side, a straight left side with an arced bottom, left corner between the left side and the bottom side. The fin 22 further defines a small-sized, substantially semicircular accommodating hole 224 therein for accommodating a solder paste 23. The accommodating hole 224 is located a top, left corner of the receiving hole 223 and communicates with the receiving hole 223.

A combining sidewall 24 extends vertically from an edge of the receiving hole 223 of the fin 22. The combining sidewall 24 includes an elongated top planar plate 241, an elongated bottom planar plate 242 opposite to the top planar plate 241, a left short plate 243 at a left side of the receiving hole 223, and a right short plate 244 at a right side of the receiving hole 233. The left short plate 243 extend substantially straight from a left end of the bottom planar plate 242 towards a left end of the top planar plate 241, while the right short plate 244 extend curvedly from a right end of the bottom planar plate 242 to a right end of the top planar plate 241. The accommodating hole 224 is located at the left end of the top planar plate 241 and a top end of the left short plate 243. In other words, the accommodating hole 224 is located at a junction of the top planar plate 241 and the left short plate 243. The accommodating hole 224 extends along a width direction of the receiving hole 223 and is located above the receiving hole 233. A combining plate 245 extends vertically from an edge of the accommodating hole 224 of the fin. The combining plate 245 is connected between the left end of the top planar plate 241 and the top end of the left short plate 243 of the combining sidewall 24. A top end of the right short plate 244 connects with a right end of the top planar plate 241. Thus, the combining plate 245 and the combining sidewall 24 cooperatively form a closed wall enclosing the receiving hole 223 and the accommodating hole 224.

Referring to FIG. 4, the flat heat pipe 21 is inserted in the receiving holes 224 of the fins 22. A clearance exists between the outer surface of the flat heat pipe 21 and the combining sidewall 24 of each fin 22 before the flat heat pipe 21 and the fins 22 being soldered together. The solder paste 23 is accommodated in the accommodating hole 224 of each fin 22. When soldering, the solder paste 23 is heated to its melting point. The molten solder paste 23 flows from the accommodating hole 224 into the receiving hole 223 of each fin 22 to fill up the clearance between the flat heat pipe 21 and the combining sidewall 24 of each fin 22 via capillary force and gravity. Referring to FIG. 5, after the molten solder paste 23 is cooled, a solder layer 231 is formed between the flat heat pipe 21 and the combining sidewall 24 of each fin 22, securely combining the flat heat pipe 21 and the fins 22 together.

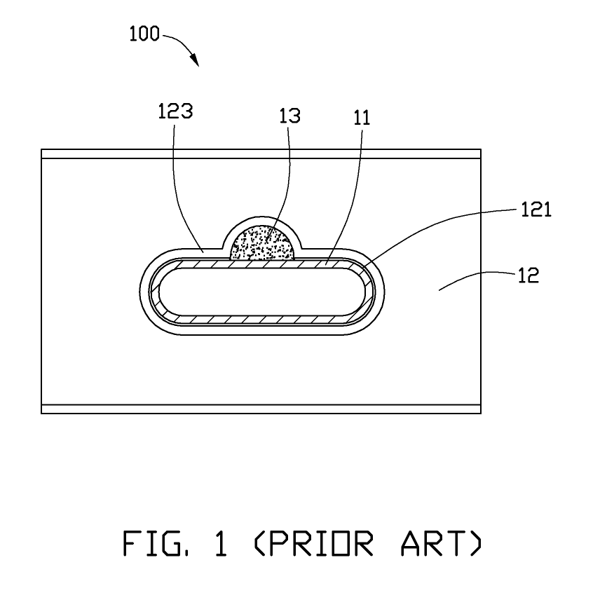

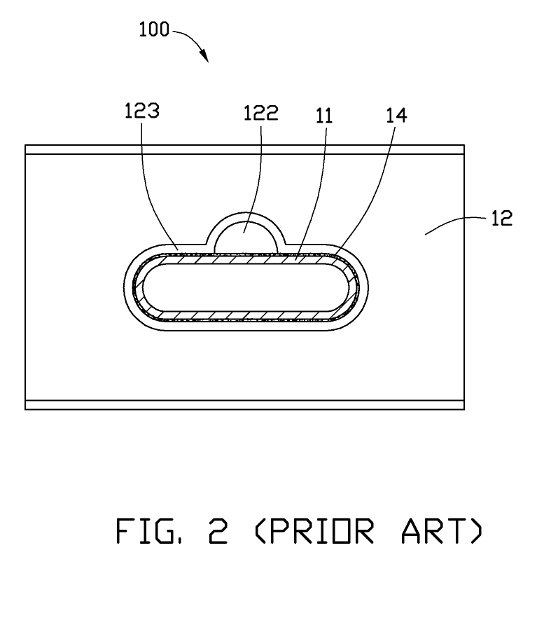

In this heat dissipation apparatus 200, the accommodating hole 224 is arranged at a corner of the receiving hole 223. The effective contacting surface of the flat heat pipe 21 (i.e., the top planar face 213 and the bottom planar face 214) is fully combined to the combining sidewalls 24 of the fins 22. Comparing with the conventional heat dissipation apparatus 100 shown in FIGS. 1 and 2, the heat transfer efficiency between the flat heat pipe 21 and the fins 22 is greatly increased. In addition, due to the accommodating hole 224 being arranged at a corner of the receiving hole 223, the molten solder paste 23 firstly flows downwardly towards the bottom planar plate 242 quickly via gravity, and then flows horizontally along the bottom planar plate 242 via capillary force. The molten solder paste 23 can fully fill up a clearance between the bottom planar face 214 of the flat heat pipe 21 and the bottom planar plate 242 of the combining sidewall 24. Thus, an insufficient soldering will not occur between the bottom planar face 214 of the flat heat pipe 21 and the bottom planar plate 242 of the combining sidewall 24. The heat transfer efficiency between the flat heat pipe 21 and the fins 22 is further increased.

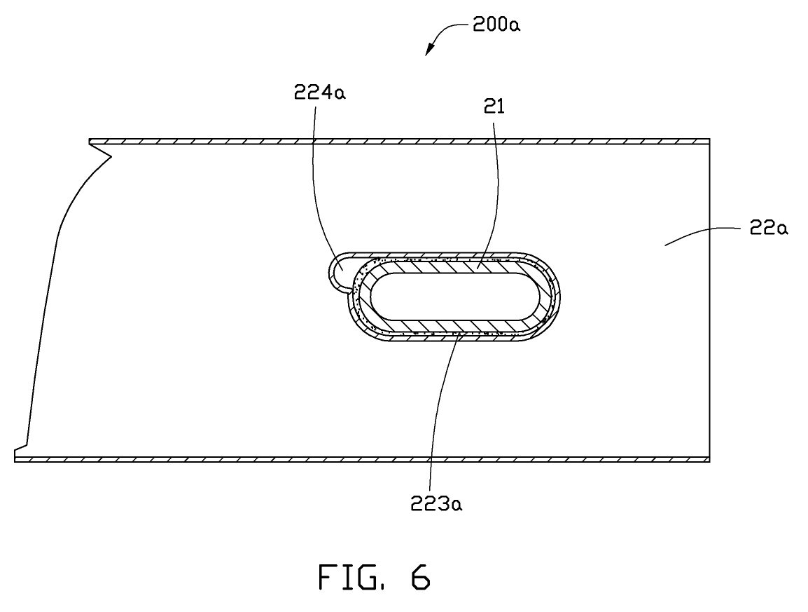

Referring to FIG. 6, a heat dissipation apparatus 200a in accordance with a second embodiment is shown. The heat dissipation apparatus 200a includes the flat heat pipe 21 and a plurality of fins 22a. Each fin 22a defines an elongated receiving hole 223a therein for receiving the flat heat pipe 21 and a small-sized accommodating hole 224a therein for accommodating solder paste. Except the following difference, the heat dissipation apparatus 200a of the present embodiment is essentially the same as the heat dissipation apparatus 200 illustrated in FIGS. 3-5. In the present embodiment, the accommodating hole 224a extends along a length direction of the receiving hole 223a and is located a left side of the receiving hole 233a.

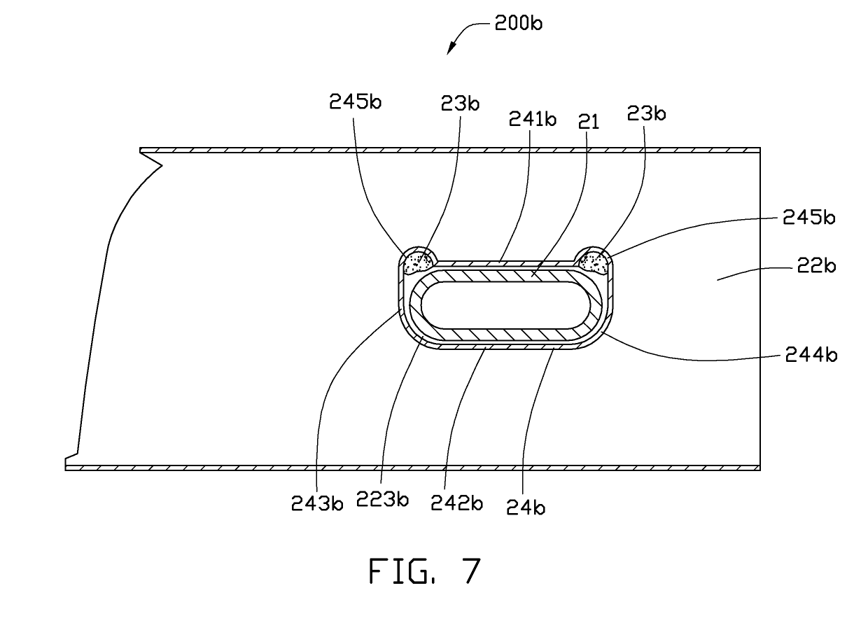

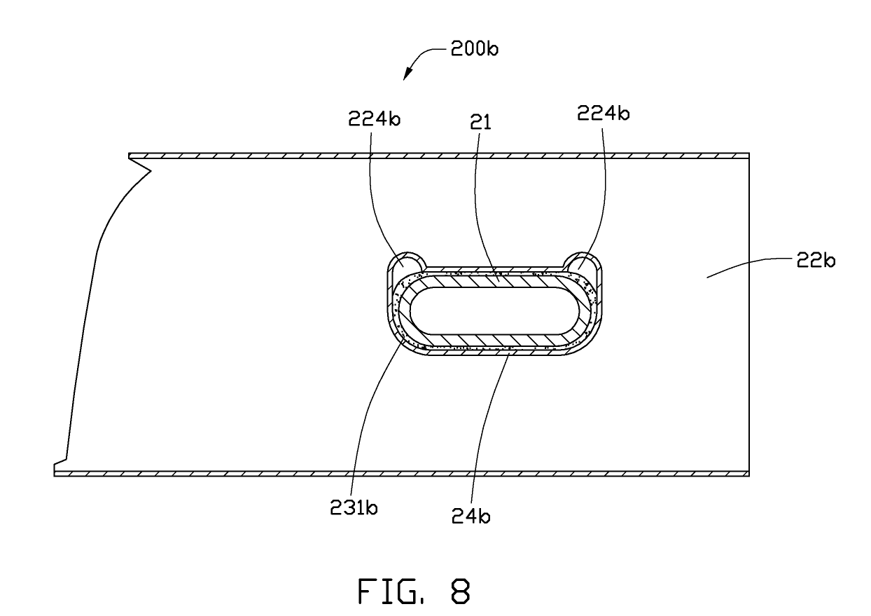

Referring to FIGS. 7 and 8, a heat dissipation apparatus 200b in accordance with a third embodiment is shown. The heat dissipation apparatus 200b includes the flat heat pipe 21 and a plurality of fins 22b. Each fin 22b defines an elongated receiving hole 223b therein for receiving the flat heat pipe 21. A combining sidewall 24b extends vertically from an edge of the receiving hole 223b of the fin 22b. The combining sidewall 24b includes an elongated top planar plate 241b, an elongated bottom planar plate 242b opposite to the top planar plate 241b, and two curved short plates 243b, 244b (i.e., left short plate 243b and right short plate 244b) at left and right sides of the receiving hole 233b. Except the following differences, the heat dissipation apparatus 200b of the present embodiment is essentially the same as the heat dissipation apparatus 200 illustrated in FIGS. 3-5. In the present embodiment, the fin 22b defines two accommodating holes 224b therein for accommodating two solder pastes 23b. The accommodating holes 224b are located at two corners of the receiving hole 223b (i.e., top left corner and top right corner of the receiving hole 223b) and communicate with the receiving hole 233b. In other words, the two accommodating holes 224b are respectively located at two ends of the top planar plate 241b and are respectively located at top ends of the two short plates 243b, 244b. One of the two accommodating holes 224b is located at a junction of the top planar plate 241b and the left short plate 243b, while the other of the two accommodating holes 224b is located at a junction of the top planar plate 241b and the right short plate 244b. The two accommodating holes 224b extend along a width direction of the receiving hole 223b and are located above the receiving hole 233b. A combining plate 245b extends vertically from an edge of each accommodating hole 224b of the fin 22b. Two ends of each combining plate 245b connect with a top end a corresponding short plate 243b (244b) and one end of the top planar plate 241b of the combining sidewall 24b. Thus, the combining plate 245b and the combining sidewall 24b cooperatively form a closed wall.

Referring to FIG. 7, the flat heat pipe 21 is inserted in the receiving holes 233b of the fins 22b. A clearance exists between the outer surface of the flat heat pipe 21 and the combining sidewall 24b of each fin 22b before the flat heat pipe 21 and the fins 22b are soldered together. Two solder pastes 23b are accommodated in the two accommodating holes 224b of each fin 22b, respectively. When soldering, the solder pastes 23b are heated to their melting point. The molten solder pastes 23b flow from the two accommodating holes 224b into the receiving hole 223b of each fin 22b to fill up the clearance between the flat heat pipe 21 and the combining sidewall 24b of each fin 22b via capillary force and gravity. Referring to FIG. 8, after the solder pastes 23b are cooled, a solder layer 231b is formed between the flat heat pipe 21 and the combining sidewall 24b of each fin 22b, securely combining the flat heat pipe 21 and the fins 22b together.

In the heat dissipation apparatus 200b of this embodiment, the two accommodating holes 224b are arranged at two corners of the receiving hole 223b (i.e., junctions of the top planar plate 241b and the two short plates 243b, 244b). The effective contacting surface of the flat heat pipe 21 (i.e., the top planar face 213 and the bottom planar face 214) is fully combined to the combining sidewalls 24b of the fins 22b. Comparing with the conventional heat dissipation apparatus 100 shown in FIGS. 1 and 2, the heat transfer efficiency between the flat heat pipe 21 and the fins 22b is greatly increased. In addition, due to the two accommodating holes 224b being arranged at two corners of the receiving hole 223b, a flow distance of the molten solder paste 23b from each accommodating hole 224b to a center portion of the bottom planar plate 242b of the combining sidewall 24b is decreased. The molten solder paste 23b can fully fill up a clearance between the bottom planar face 214 of the flat heat pipe 21 and the bottom planar plate 242b of the combining sidewall 24b. Thus, an insufficient soldering will not occur between the bottom planar face 214 of the flat heat pipe 21 and the bottom planar plate 242b of the combining sidewall 24b. The heat transfer efficiency between the flat heat pipe 21 and the fins 22b is further increased.

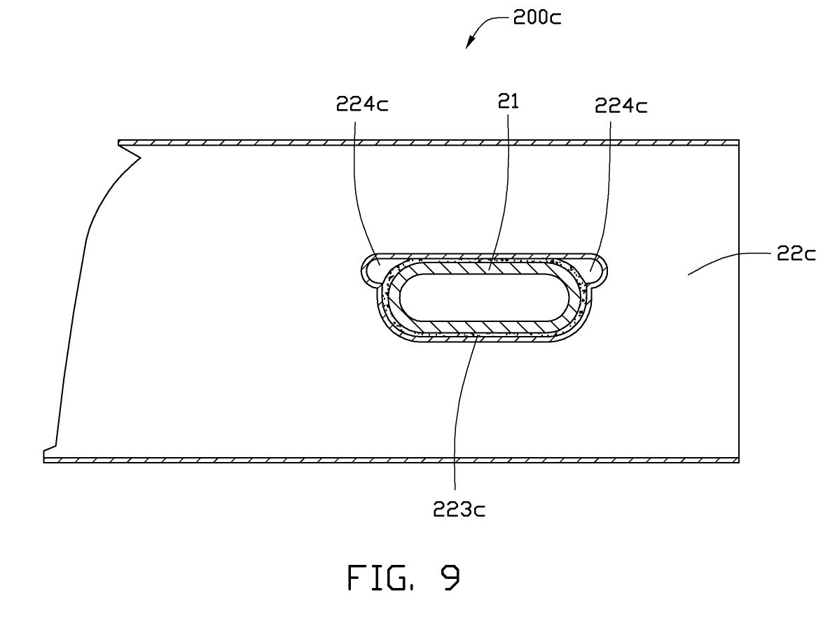

Referring to FIG. 9, a heat dissipation apparatus 200c in accordance with a fourth embodiment is shown. The heat dissipation apparatus 200c includes the flat heat pipe 21 and a plurality of fins 22c. Each fin 22c defines an elongated receiving hole 223c therein for receiving the flat heat pipe 21 and two small-sized accommodating holes 224c therein for accommodating solder pastes. Except the following difference, the heat dissipation apparatus 200c of the present embodiment is essentially the same as the heat dissipation apparatus 200b illustrated in FIGS. 7-8. In the present embodiment, the two accommodating holes 224c extend along a length direction of the receiving hole 223c and are located left and right sides of the receiving hole 233c.

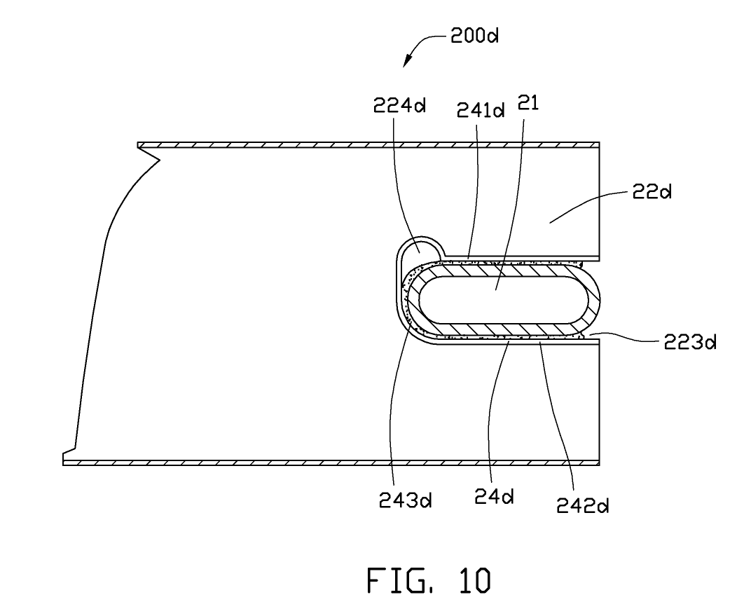

Referring to FIG. 10, a heat dissipation apparatus 200d in accordance with a fifth embodiment is shown. The heat dissipation apparatus 200d includes the flat heat pipe 21 and a plurality of fins 22d. Each fin 22d defines an elongated receiving hole 223d therein for receiving the flat heat pipe 21 and a small-sized accommodating hole 224d therein for accommodating solder paste. A combining sidewall 24d extends vertically from an edge of the receiving hole 223d of the fin 22d. The combining sidewall 24d includes an elongated top planar plate 241d, an elongated bottom planar plate 242d opposite to the top planar plate 241d, and a curved short plate 243d at a left side of the receiving hole 233d. The accommodating hole 224d is located at a junction of the top planar plate 241d and the left short plate 243d. Except the following difference, the heat dissipation apparatus 200d of the present embodiment is essentially the same as the heat dissipation apparatus 200 illustrated in FIGS. 3-5. In the present embodiment, a right side of the receiving hole 223d (i.e., a side opposite to the left short plate 243d) is open.

It is to be understood, however, that even though numerous characteristics and advantages of the disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A heat dissipation apparatus, comprising:
a flat heat pipe having a condenser section, and
a plurality of fins stacked together, each of the fins defining a substantially rectangular-shaped receiving hole therein for receiving the condenser section of the flat heat pipe and a small-sized accommodating hole therein for accommodating a solder paste, a combining sidewall extending from an edge of the receiving hole of each of the fins, the combining sidewall comprising an elongated top planar plate, an elongated bottom planar plate opposite to the top planar plate, and a short plate extending from one end of the bottom planar plate towards the top planar plate, the accommodating hole being located at a junction of the top planar plate and the short plate of the combining sidewall, the condenser section of the flat heat pipe being inserted in the receiving holes of the fins, the solder paste accommodated in the accommodating hole being heated to melt, the molten solder paste flowing from the accommodating hole into the receiving hole of each of the fins to fill up a clearance between the flat heat pipe and the combining sidewall of each of the fins to combine the flat heat pipe and the fins together after the molten solder paste is cooled.

2. The heat dissipation apparatus of claim 1, wherein the combining sidewall further comprises an additional short plate extending from another end of the bottom planar plate towards the top planar plate to connect with the top planar plate.

3. The heat dissipation apparatus of claim 2, wherein a combining plate extends from an edge of the accommodating hole of each of the fins, the combining plate and the combining sidewall cooperatively forming a closed wall.

4. The heat dissipation apparatus of claim 1, wherein the combining sidewall further comprises an additional short plate extending from another end of the bottom planar plate towards the top planar plate, each of the fins further defining an additional small-sized accommodating hole therein for accommodating another solder paste, the additional accommodating hole being located at a junction of the top planar plate and the additional short plate of the combining sidewall.

5. The heat dissipation apparatus of claim 4, wherein a combining plate extends from an edge of each of the two accommodating holes, the combining plates and the combining sidewall cooperatively forming a closed wall.

6. The heat dissipation apparatus of claim 1, the accommodating hole extends along a width direction of the receiving hole and is located above the receiving hole.

7. The heat dissipation apparatus of claim 1, wherein the accommodating hole extends along a length direction of the receiving hole and is located a lateral side of the receiving hole.

8. The heat dissipation apparatus of claim 1, wherein a side of the receiving hole opposite to the short plate is open.

9. The heat dissipation apparatus of claim 1, wherein a combining plate extends from an edge of the accommodating hole of each of the fins, the combining plate being connected between the top planar plate and the bottom planar plate.

10. A heat dissipation apparatus, comprising:
a flat heat pipe having a condenser section, and
a plurality of fins stacked together, each of the fins defining a substantially rectangular-shaped receiving hole with a size larger than an outer size of the condenser section of the flat heat pipe and at least one small-sized accommodating hole being located at a corner of the receiving hole and communicating the receiving hole, the condenser section of the flat heat pipe being inserted in the receiving holes of the fins, when the heat dissipation apparatus is assembled, a solder paste is accommodated in the at least one accommodating hole and heated to melt, the molten solder paste flowing from the at least one accommodating hole into the receiving hole of each of the fins to fill up a clearance between the flat heat pipe and a combining sidewall surrounding the receiving hole of each of the fins to combine the flat heat pipe and the fins together after the molten solder paste is cooled.

11. The heat dissipation apparatus of claim 10, wherein the at least one accommodating holes comprises two accommodating holes located at two adjacent corners of the receiving hole, each accommodating hole receiving a solder paste therein.

12. The heat dissipation apparatus of claim 11, wherein the two accommodating holes extend along a length direction of the receiving hole and are located at two sides of the receiving hole.

13. The heat dissipation apparatus of claim 11, wherein the two accommodating holes extend along a width direction of the receiving hole and are located above the receiving hole.

14. The heat dissipation apparatus of claim 10, wherein a combining plate extends from an edge of the at least one accommodating hole, the combining plate and the combining sidewall cooperatively forming a closed wall.
